(19) United States
(12) Patent Application Publication
(10) Pub. No.: US 2023/0118921 A1
(43) Pub. Date: Apr. 20, 2023

(54) MONITORING DEVICE FOR BATTERY

(71) Applicant: TOYOTA JIDOSHA KABUSHIKI KAISHA, Toyota-shi (JP)

(72) Inventors: Tsubasa MIGITA, Chiryu-shi (JP); Yoshihiro UCHIDA, Nagakute-shi (JP); Hiroshi YOSHIDA, Anjo-shi (JP)

(73) Assignee: TOYOTA JIDOSHA KABUSHIKI KAISHA, Toyota-shi (JP)

(21) Appl. No.: 17/820,021

(22) Filed: Aug. 16, 2022

(30) Foreign Application Priority Data
Oct. 15, 2021 (JP) 2021-169436

(51) Int. Cl. G01R 31/3835; H02J 7/35; H01M 10/48; H02J 7/00; B60L 50/60

(52) U.S. Cl. CPC G01R 31/3835; H02J 7/35; H01M 10/482; H02J 7/0047; B60L 50/60; H01M 2220/20

(57) ABSTRACT

A monitoring device for a battery that supplies electric power to a traction motor of a vehicle includes a sensor that detects a voltage of a battery cell of the battery, and a processing circuit that executes abnormality detection processing for detecting an abnormality in the battery, based on a detected voltage value that is detected by the sensor. The processing circuit executes processing for identifying a first elapsed time from a main switch of the vehicle being turned off until charging or discharging is started between the battery and predetermined on-board equipment, processing for identifying a second elapsed time from starting of the charging or discharging between the battery and the on-board equipment to a current point in time, and the abnormality detection processing when a total time of the first elapsed time and the second elapsed time reaches a predetermined threshold value.

### CROSS-REFERENCE TO RELATED APPLICATION

This application claims priority to Japanese Patent Application No. 2021-169436 filed on Oct. 15, 2021, incorporated herein by reference in its entirety.

### BACKGROUND

### 1. Technical Field

The technology disclosed in the present specification relates to a monitoring device for a battery that supplies electric power to a traction motor of a vehicle.

### 2. Description of Related Art

Japanese Unexamined Patent Application Publication No. 2000-260481 (JP 2000-260481 A) describes a monitoring device for a battery that has a plurality of battery cells. This monitoring device is configured to detect a battery abnormality by monitoring deviation in internal resistance occurring among the battery cells.

### SUMMARY

Another conceivable technique of monitoring the battery is to monitor voltage of the battery cells. Note however, that the voltage of the battery cells changes according to current flowing through the battery. Accordingly, in order to correctly detect an abnormality in the battery, measuring open circuit voltage (OCV) of the battery, while a vehicle is parked, for example is effective. In this case, in order to eliminate the influence of the battery usage history on the open circuit voltage, the open circuit voltage of the battery is preferably measured after a certain period of time has elapsed from the end of charging/discharging of the battery.

However, in recent vehicles, a solar charging system may charge the battery, or the battery may be discharged to an auxiliary battery, even while the vehicle is parked. In such charging/discharging, the current flowing through the battery is relatively small, and the influence of the usage history on the open circuit voltage of the battery is relatively suppressed. Accordingly, as described above, uniformly imposing a condition such as measuring the open circuit voltage of the battery after a certain period of time has elapsed since the charging/discharging of the battery ending, may cause detection of abnormality of the battery to be excessively restricted.

In view of the above circumstances, the present disclosure provides a technology for reducing excessive limitation on detection of battery abnormalities.

The technology in the present disclosure is embodied in a monitoring device for monitoring a battery that supplies electric power to a traction motor of a vehicle. The monitoring device includes a sensor that detects a voltage of a battery cell of the battery, and a processing circuit that executes abnormality detection processing for detecting an abnormality in the battery, based on a detected voltage value that is detected by the sensor. The processing circuit is configured to identify a first elapsed time from a main switch of the vehicle being turned off until charging or discharging is started between the battery and predetermined on-board equipment, identify a second elapsed time from starting of the charging or discharging between the battery and the on-board equipment to a current point in time, and execute the abnormality detection processing when a total time of the first elapsed time and the second elapsed time reaches a predetermined threshold value.

According to research carried out by the present inventors, a C-rate is sufficiently small for charging or discharging between the battery and predetermined on-board equipment (e.g., a solar charging system), and it was confirmed that such charging or discharging does not influence open circuit voltage of the battery. Accordingly, findings have been made that abnormalities of the battery can be correctly detected, even when charging or discharging is being performed between the battery and predetermined equipment. Note that the C-rate referred to here is an index indicating the rate of charging or discharging with respect to the capacity of the battery, and a magnitude of current by which the capacity of the battery is fully charged (or fully discharged) in one hour is defined as 1C.

Based on the above findings, in the technology of the present disclosure, the processing circuit executes abnormality detection processing when the total time of the first elapsed time and the second elapsed time reaches a predetermined threshold. Now, the first elapsed time is time from the main switch of the vehicle being turned off until charging or discharging is started between the battery and the predetermined on-board equipment. The second elapsed time is time from the start of charging or discharging between the battery and the predetermined on-board equipment to the current point in time. According to such a configuration, the processing circuit can detect abnormalities of the battery even when charging or discharging between the battery and the predetermined on-board equipment is being performed. That is to say, the abnormality determination processing is executed even though a certain amount of time has not elapsed since the charging or discharging between the battery and the predetermined on-board equipment is ended. Thus, excessive limitation of detection of abnormalities of the battery can be suppressed.

### BRIEF DESCRIPTION OF THE DRAWINGS

Features, advantages, and technical and industrial significance of exemplary embodiments will be described below with reference to the accompanying drawings, in which like signs denote like elements, and wherein:

FIG. 1 is a schematic diagram illustrating a configuration a monitoring device 10 and a vehicle 100 according to a first embodiment;

FIG. 2 is a flowchart showing a sequence of processing executed by a processing circuit 14;

FIG. 3 is a schematic diagram illustrating a configuration of the monitoring device 10 and a vehicle 200 according to a second embodiment; and

FIG. 4 is a schematic diagram illustrating a configuration of the monitoring device 10 and a vehicle 300 according to a third embodiment.

### DETAILED DESCRIPTION OF EMBODIMENTS

According to an embodiment of the present technology, on-board equipment may be equipment in which charging or discharging with respect to a battery is carried out at a C-rate of 0.1 C or lower. Influence of charging or discharging of the battery on open circuit voltage is thought to be sufficiently small when charging or discharging is carried out at such a C-rate. In the above embodiment, the on-board equipment may be equipment in which charging or discharging with respect to the battery is carried out at a C-rate of 0.05 C or lower. In the above embodiments, the on-board equipment may be equipment in which charging or discharging with respect to the battery is carried out at a C-rate of 0.01 C or lower. Thus, the lower the C-rate of charging/discharging between the battery and the on-board equipment is, the more sufficiently the influence of charging or discharging of the battery on the open circuit voltage can be anticipated to be suppressed or eliminated.

According to an embodiment of the present technology, the on-board equipment may be a solar charging system. In this case, the charging or discharging between the battery and the on-board equipment may be charging from the solar charging system to the battery. In place of or in addition to the embodiments described above, the on-board equipment may be an auxiliary battery. In this case, the charging or discharging between the battery and the on-board equipment may be discharging from the battery to the auxiliary battery. Further, instead of or in addition to these embodiments, the on-board equipment may be a power feed port to external equipment. In this case, the charging or discharging between the battery and the on-board equipment may be discharging from the battery to the power feed port. It should be noted that these pieces of on-board equipment are typical examples of equipment in which influence on the open circuit voltage, due to charging or discharging between the equipment and the battery, is sufficiently small.

According to an embodiment of the present technology, the battery may include a plurality of battery cells. In this case, a sensor may detect a voltage value of each of the battery cells. In this case, in abnormality detection processing, a processing circuit may compare a difference between detected voltage values in two adjacent battery cells with a predetermined determination reference value. According to such a configuration, in a cell stack in which the battery cells are arrayed stacked, for example, influence of temperature deviation among the battery cells can be suppressed, and abnormalities of the battery can be detected with high accuracy. Note however, that the battery does not necessarily have to include multiple battery cells, and including at least one battery cell is sufficient. Also, the sensor does not necessarily have to detect the voltage value of each of the battery cells, and may detect the voltage value of the entirety of battery cells.

### First Embodiment

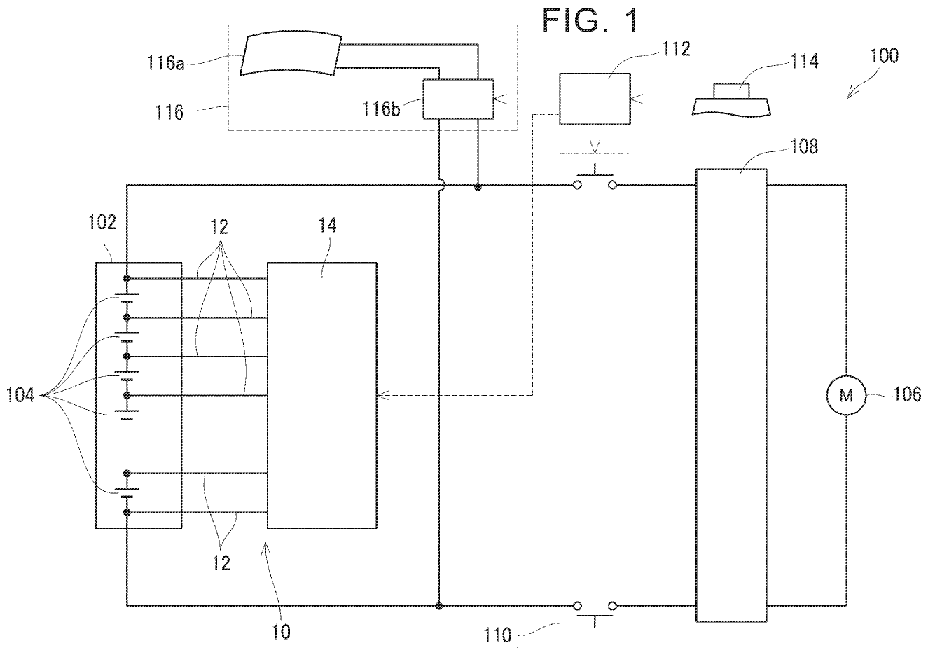

A monitoring device 10 according to a first embodiment, and a vehicle 100 employing the same, will be described with reference to the drawings. As illustrated in FIG. 1, the monitoring device 10 is a device for monitoring a battery 102, and in particular, monitoring the state of the battery 102 that supplies electric power to a motor 106 of the vehicle 100 for traveling. The vehicle 100 here is a so-called automobile, and is a vehicle that travels over a road surface. The term “road surface” here is not limited to so-called public roads, and also refers to private land and indoor floor surfaces over which vehicles can travel. The vehicle 100 is, for example, an engined vehicle, a hybrid electric vehicle, a fuel cell electric vehicle, a battery electric vehicle, a solar vehicle, or the like. Note that the technology described in the present embodiment is not limited to vehicles that travel over road surfaces but can also be effectively employed in vehicles that travel on tracks. Further, the technology disclosed in the present embodiment is not limited to the vehicle 100, and can be employed in moving bodies such as watercrafts, aircrafts, and so forth.

As illustrated in FIG. 1, the vehicle 100 includes the battery 102. The battery 102 is a secondary battery in which a plurality of battery cells 104 is connected in series. Note that the specific count of the battery cells 104 is not limited in particular, and it is sufficient for count to be at least one. Each of the battery cells 104 is, for example, a lithium-ion battery. However, the battery cells 104 do not necessarily have to each be a lithium-ion battery, and may be another type of battery such as a nickel metal hydride battery.

As illustrated in FIG. 1, the vehicle 100 further includes the motor 106 and an inverter 108. The motor 106 is a traction motor that drives wheels of the vehicle 100, and is a three-phase motor generator that has a U phase, a V phase, and a W phase, in the present embodiment. The inverter 108 is a device that performs electric power conversion between direct current and alternating current, between the battery 102 and the motor 106. The inverter 108 is provided between the battery 102 and the motor 106, and is capable of converting direct current power from the battery 102 into three-phase alternating current electric power, and supplying the three-phase alternating current electric power to the motor 106. The inverter 108 is also capable of converting the three-phase alternating current electric power from the motor 106 into direct current power and supplying the direct current power to the battery 102. When rated voltage of the battery 102 and rated voltage of the motor 106 are different from each other, a direct current (DC)-to-DC converter may be further provided between the battery 102 and the inverter 108, although this is not limiting in particular.

As illustrated in FIG. 1, the vehicle 100 further includes a pair of relays 110, a control device 112, and a main switch 114. The relays 110 are provided between the battery 102 and the inverter 108, and are capable of electrically connecting and disconnecting the battery 102 and the inverter 108 to and from each other. Turning the relays 110 on and off is controlled by the control device 112, for example. Regardless of the state of the main switch 114, the control device 112 is always operating, by receiving electric power supply from an auxiliary battery (omitted from illustration). When the main switch 114 of the vehicle 100 is turned off, the control device 112 electrically connects the battery 102 and the inverter 108 to each other by turning on the relays 110. In comparison, when the main switch 114 is turned on, the control device 112 electrically disconnects the battery 102 and the inverter 108 from each other by turning off the relays 110. However, as another embodiment, the relays 110 may be turned on and off by the user instead of by the control device 112. There are cases in which the main switch 114 of the vehicle 100 is referred to as an ignition switch, in accordance with the tradition for engined vehicles.

As illustrated in FIG. 1, the vehicle 100 further includes a solar charging system 116. The solar charging system 116 mainly includes a solar panel 116a and a DC-to-DC converter 116b. The solar panel 116a is connected to the battery 102 via the DC-to-DC converter 116b. The solar charging system 116 can charge the battery 102 by electric power generated by the solar panel 116a. The operation of the DC-to-DC converter 116b is controlled by the control device 112. The control device 112 can start or stop charging the battery 102 by the solar charging system 116 by controlling the operation of the DC-to-DC converter 116b. When starting or stopping charging by the solar charging system 116, the control device 112 transmits a notification corresponding thereto (e.g., a charging start notification or a charging stop notification) to a processing circuit 14 of the monitoring device 10. The solar charging system 116 is electrically connected to the battery 102, without going through the relays 110. Accordingly, the solar charging system 116 can charge the battery 102 not only when the relays 110 are turned on, but also when turned off. Now, the solar charging system 116 according to the present embodiment is an example of predetermined on-board equipment according to the technology disclosed in the present specification.

The C-rate in charging the battery 102 by the solar charging system 116 is sufficiently small, such as 0.1 C or lower, for example. Note that in a sequence of processing executed by the processing circuit 14 which will be described later, the C-rate in charging the battery 102 by the solar charging system 116 is preferably small, and for example may be 0.05 C or lower, and further may be 0.01 C or lower.

Next, the monitoring device 10 will be described. As illustrated in FIG. 1, the monitoring device 10 includes voltage detection circuits 12 and the processing circuit 14. Note that the monitoring device 10 may be configured as a single battery unit along with the battery 102, although this is not limiting in particular. The voltage detection circuits 12 are circuits for detecting the voltage of the battery cells 104 included in the battery 102. The processing circuit 14 is capable of monitoring the state of the battery cells 104, including the voltage of each battery cell 104. The voltage detection circuits 12 are electrically connected to respective battery cells 104, and can detect the voltage value of each of the battery cells 104. The voltage detection circuits 12 are electrically connected to the processing circuit 14, and can input potential at both terminals of each battery cell 104 to the processing circuit 14. The processing circuit 14 can acquire the voltage values of the respective battery cells 104 based on the input from the voltage detection circuits 12. The processing circuit 14 is configured to be able to execute abnormality detection processing for detecting an abnormality in the battery 102 based on the detected voltage value. Note that the voltage detection circuits 12 in the present embodiment are an example of a sensor that detects voltage of a battery cell 104.

In the present embodiment, the monitoring device 10 is monitored and controlled by the control device 112, for example. When the main switch 114 of the vehicle 100 is turned on, the control device 112 turns on the relays 110 and starts up the processing circuit 14 of the monitoring device 10. When the main switch 114 of the vehicle 100 is turned off, the control device 112 turns off the relays 110 and stops the processing circuit 14 of the monitoring device 10. The processing circuit 14 is configured to activate a tinier built into the processing circuit 14 when entering a sleep state. Thus, the processing circuit 14 can measure the amount of time over which the main switch 114 of the vehicle 100 is turned off. The monitoring device 10 operates under electric power supplied from the auxiliary battery, although this is omitted from illustration.

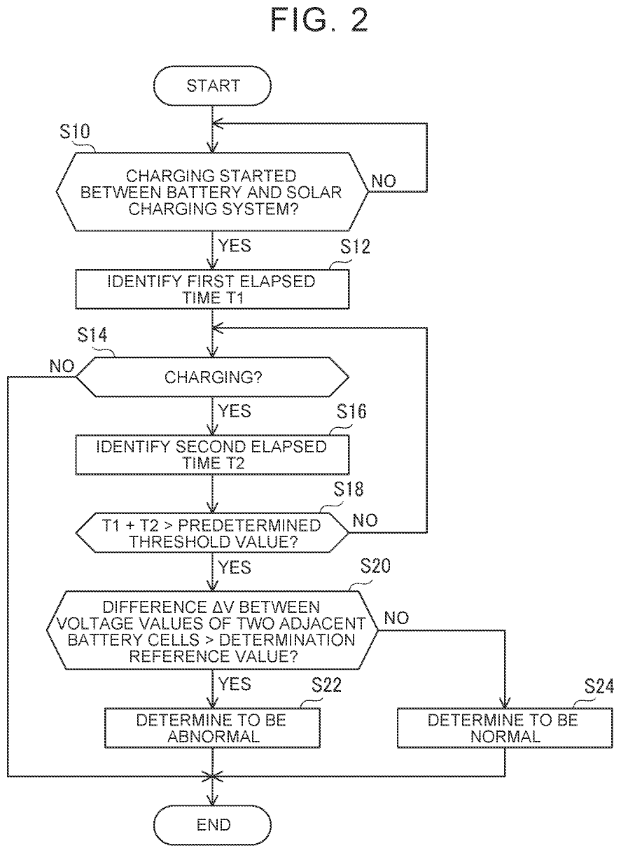

Next, the sequence of processing executed by the processing circuit 14 will be described with reference to FIG. 2. The processing circuit 14 executes the sequence of processing when the main switch 114 of the vehicle 100 is turned off. Now, the main switch 114 of the vehicle 100 is turned off mainly when the vehicle 100 is parked.

As shown in FIG. 2, in step S10, the processing circuit 14 determines whether charging has started between the battery 102 and the solar charging system 116. As described above, when charging between the battery 102 and the solar charging system 116 is started, the control device 112 transmits a charging start notification to the processing circuit 14 of the monitoring device 10. Upon receiving the notification (YES in step S10), the processing circuit 14 transitions to the processing of step S12.

In step S12, the processing circuit 14 identifies a first elapsed time T1. The first elapsed time T1 here is the time from when the main switch 114 of the vehicle 100 is turned off until charging is started between the battery 102 and the solar charging system 116. As described above, when the main switch 114 of the vehicle 100 is turned off, the processing circuit 14 starts measuring the time of the main switch 114 of the vehicle 100 being off, using the timer that is built in. The processing circuit 14 then identities the timing at which charging is started between the battery 102 and the solar charging system 116 based on the charging start notification from the control device 112. Thus, the processing circuit 14 identifies the first elapsed time T1.

In step S14, the processing circuit 14 determines whether charging is being continued between the battery 102 and the solar charging system 116. As described above, when charging between the battery 102 and the solar charging system 116 is stopped, the control device 112 transmits a charging stop notification to the processing circuit 14 of the monitoring device 10. Accordingly, unless a charging stop notification from the control device 112 is received, the processing circuit 14 makes a determination of YES in step S14 and transitions to step S16. On the other hand, when a charge stop notification is received from the control device 112, the processing circuit 14 makes a determination of NO in step S14, and ends the sequence of processing.

In step S16, the processing circuit 14 identifies a second elapsed time T2. Here, the second elapsed time T2 is the time from starting charging between the battery 102. and the solar charging system 116 to the current point in time. The processing circuit 14 uses the timer that is built in to measure the time from the timing of measurement of the first elapsed time T1 ending to the current point in time, thereby identifying the second elapsed time T2. Note that the second elapsed time T2 does not necessarily have to be identified separately from the first elapsed time T1, and may be identified collectively with the first elapsed time T1. That is to say, the processing circuit 14 may identify the first elapsed time T1 and the second elapsed time T2 collectively, by identifying the time from the main switch 114 of the vehicle 100 being turned off to the current point in time at which charging is continuing between the battery 102 and the solar charging system 116.

In step S18, the processing circuit 14 determines whether the total time of the first elapsed time T1 and the second elapsed time T2 has reached a predetermined threshold value. Note that the predetermined threshold value for the total time can be selected from a data group stored in advance in the processing circuit 14, in accordance with the capacity, count, type, and so forth of the battery cells 104, although this is not limiting in particular. When the total time of the first elapsed time T1 and the second elapsed time T2 has reached the predetermined threshold value (YES in step S18), the processing circuit 14 transitions to step S20. On the other hand, when the total time of the first elapsed time T1 and the second elapsed time T2 has not reached the predetermined threshold value (NO in step S18), the processing circuit 14 returns to the processing of step S14. Thus, the processing circuit 14 repeats the processing from step S14 to step S18 until the total time of the first elapsed time TI and the second elapsed time T2 reaches the predetermined threshold value, as long as charging between the battery 102 and the solar charging system 116 continues.

In step S20, the processing circuit 14 executes the abnormality detection processing. In this abnormality detection processing, abnormalities in the battery 102 are detected based on the detected voltage values that are detected by the voltage detection circuits 12. As an example, the processing circuit 14 determines whether a difference ΔV between the detected voltage values in two adjacent battery cells 104 exceeds a predetermined determination reference value. Note that the predetermined determination reference value can be selected from a data group stored in advance in the processing circuit 14, in accordance with the capacity, type, and so forth of the battery cells 104, although this is not limiting in particular, When the difference ΔV between the detected voltage values in the two adjacent battery cells 104 exceeds a predetermined determination reference value (YES in step S20), the processing circuit 14 determines that an abnormality is occurring in the battery 102. (step S22). Upon finishing the processing of step S22, the processing circuit 14 ends the sequence of processing. At this time, the processing circuit 14 may notify the control device 112 that the abnormality is occurring in the battery 102, as necessary.

When the difference ΔV between the detected voltage values in the two adjacent battery cells 104 is no greater than a predetermined determination reference value (NO in step S20), the processing circuit 14 determines that the battery 102 is normal (step S24). Upon finishing the processing of step S24 as well, the processing circuit 14 ends the sequence of processing. Note that as another embodiment, when NO is set in step S20, the processing circuit 14 may further determine whether the difference ΔV between the detected voltage values in the two adjacent battery cells 104 is no greater than a predetermined normal reference value. In this case, the processing circuit 14 may determine that the battery 102 is normal when the difference ΔV between the detected voltage values in the two adjacent battery cells 104 is no greater than a predetermined normal reference value.

As described above, in the monitoring device 10 according to the first embodiment, the processing circuit 14 executes the abnormality detection processing (step S20) when the total time of the first elapsed time T1 and the second elapsed time T2 reaches a predetermined threshold value (YES in step S18). The first elapsed time T1 here is the time from the main switch 114 of the vehicle 100 being turned off until charging is started between the battery 102 and the solar charging system 116. The second elapsed time T2 is the time from starting charging between the battery 102 and the solar charging system 116 to the current point in time.

As described above, charging between the battery 102 and the solar charging system 116 does not influence the open circuit voltage of the battery 102, since the C-rate is sufficiently small. Accordingly, the processing circuit 14 can correctly detect abnormalities in the battery 102 even when charging is being performed between the battery 102 and the solar charging system 116. That is to say, the processing circuit 14 can execute the abnormality determination processing, even though a certain amount of time has not elapsed following the charging between the battery 102 and the solar charging system 116 ending. Thus, excessive limitation of detection of abnormalities of the battery 102 can be suppressed.

### Second Embodiment

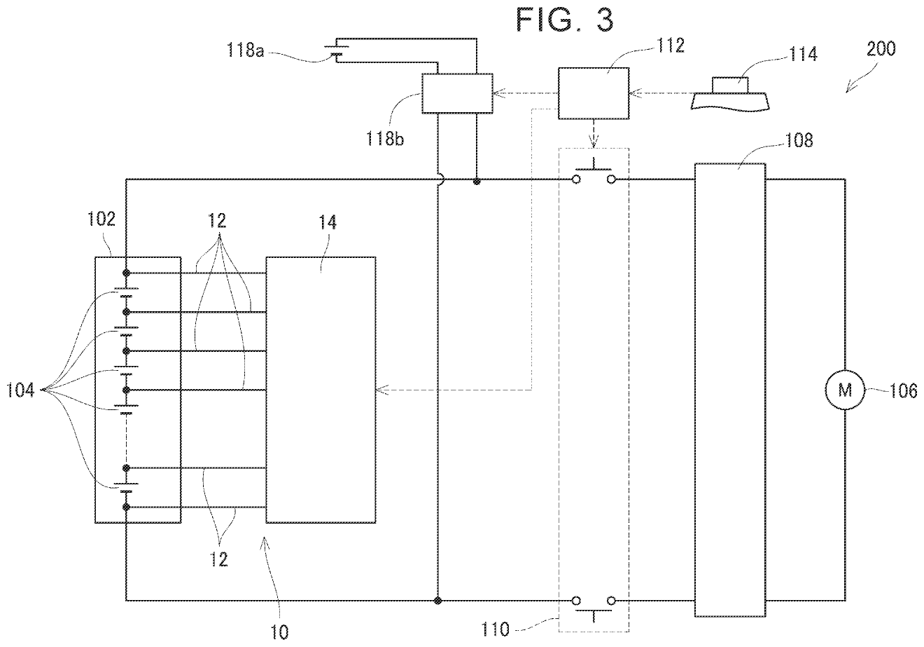

Next, the monitoring device 10 and a vehicle 200 according to a second embodiment will be described. In comparison to the vehicle 100 according to the first embodiment, the vehicle 200 according to the present embodiment includes an auxiliary battery 118a (and a DC-to-DC converter 118b) instead of the solar charging system 116. Note however, that the vehicle 200 according to the present embodiment may further include the solar charging system 116 described in the first embodiment in addition to the auxiliary battery 118a. It should be noted that other configurations are in common between the first embodiment and the present embodiment. Repetitive description will be omitted here by denoting the common configurations by the same signs. The configuration of the monitoring device 10 and the vehicle 200 according to the second embodiment will be described below with reference to FIG. 3.

As illustrated in FIG. 3, the vehicle 200 further includes the auxiliary battery 118a and the DC-to-DC converter 118b. The auxiliary battery 118a is connected to the battery 102 via the DC-to-DC converter 118b. Accordingly, the auxiliary battery 118a can be charged by discharge from the battery 102. The operation of the DC-to-DC converter 118b is controlled by the control device 112. The control device 112 can start or stop charging the auxiliary battery 118a by the battery 102, by controlling he operation of the DC-to-DC converter 118b. The auxiliary battery 118a and the DC-to-DC converter 118b are electrically connected to the battery 102 without going through the relays 110. Accordingly, the battery 102. can charge the auxiliary battery 118a not only when the relays 110 are turned on, but also when turned off. Now, the auxiliary battery 118a according to the present embodiment is also an example of predetermined on-board equipment according to the technology disclosed in the present specification.

in charging the auxiliary battery 118a by the battery 102, the C-rate in discharging from the battery 102 to the auxiliary battery 118a is sufficiently small, and the C-rate is 0.1 C or lower, for example. Accordingly, the discharging of the battery 102 at the time of this charging does not influence the open circuit voltage of the battery 102, in the same way as when performing charging by the solar charging system 116 according to the first embodiment. Thus, the processing circuit 14 can correctly detect abnormalities of the battery 102 through the sequence of processing shown FIG. 2, even when the auxiliary battery 118a is being charged by the battery 102. That is to say, the processing circuit 14 can execute the abnormality determination processing, even though a certain amount of time has not elapsed following charging of the auxiliary battery 118a by the battery 102 ending. Thus, excessive limitation of detection of abnormalities of the battery 102 can be suppressed. Note that the term “charging” in the sequence of processing shown in FIG. 2 should be read as “charging the auxiliary battery 118a” in the present embodiment.

### Third Embodiment

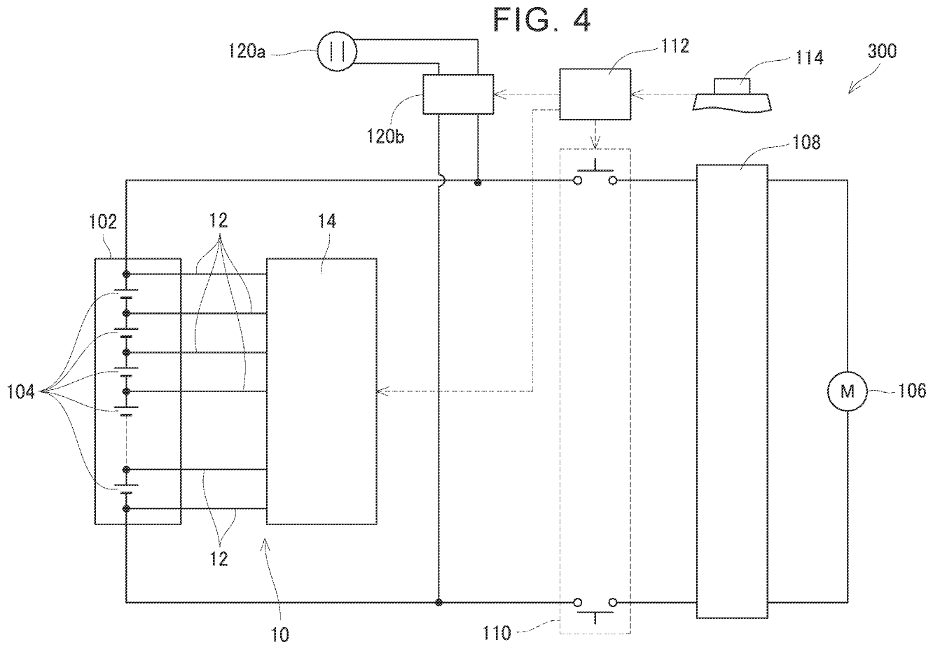

Next, the monitoring device 10 and a vehicle 300 according to a third embodiment will be described. In comparison to the vehicle 100 according to the first embodiment, the vehicle 300 according to the present embodiment includes a power feed port 120a to external equipment (and an inverter 120b) instead of the solar charging system 116. Note however, that the vehicle 300 according to the present embodiment may further include one or both of the solar charging system 116 and the auxiliary battery 118a (and the DC-to-DC converter 118b) in addition to the power feed port 120a to the external equipment. It should be noted that other configurations are in common between the first embodiment and the present embodiment. Repetitive description will be omitted here by denoting the common configurations by the same signs. The configuration of the monitoring device 10 and the vehicle 300 according to the third embodiment will be described below with reference to FIG. 4.

As illustrated in FIG. 4, the vehicle 300 further includes the power feed port 120a to external equipment and the inverter 120b. The power feed port 120a to the external equipment is connected to the battery 102 via the inverter 120b. Accordingly, the battery 102 can feed power to the external equipment by discharge to the power feed port 120a. The operation of the inverter 120b is controlled by the control device 112. The control device 112 can start or stop performing power feed to the external equipment by the battery 102, by controlling the operation of the inverter 120b. The control device 112 can stop the power feeding when the power feed of electric power to the external equipment by the battery 102 exceeds a predetermined threshold value (e.g., several hundred watts), although this is not limiting in particular. The power feed port 120a and the inverter 120b are electrically connected to the battery 102 without going through the relays 110. Accordingly, the battery 102 can perform power feed to the external equipment not only when the relays 110 are turned on, but also when turned off. Now, the power feed port 120a according to the present embodiment is also an example of predetermined on-board equipment according to the technology disclosed in the present specification.

In the power feed to the external equipment by the battery 102, the C-rate the discharge from the battery 102 to the power feed port 120a is sufficiently small, 0.1 C or lower for example. Accordingly, the discharging of the battery 102 at the time of this power feed does not influence the open circuit voltage of the battery 102, in the same way as when performing charging by the solar charging system 116 according to the first embodiment. Thus, the processing circuit 14 can correctly detect abnormalities of the battery 102 through the sequence of processing shown in FIG. 2, even when power feed is being performed to the external equipment by the battery 102. That is to say, the processing circuit 14 can execute the abnormality determination processing, even though a certain amount of time has not elapsed following power feed to the external equipment by the battery 102 ending. Thus, excessive limitation of detection of abnormalities of the battery 102 can be suppressed. Note that the term “charging” in the sequence of processing shown in FIG. 2 should be read as “discharging” in the present embodiment.

While the several specific examples have been described in detail above, these are only exemplary and do not limit the scope of the claims. The technology defined in the claims includes various modifications and alterations of the specific examples described above. The technical elements described in the present specification or in the drawings exhibit their technical usefulness alone or in combination.

What is claimed is:

1. A monitoring device for monitoring a battery that supplies electric power to a traction motor of a vehicle, the monitoring device comprising:
a sensor that detects a voltage of a battery cell of the battery; and
a processing circuit that executes abnormality detection processing for detecting an abnormality in the battery, based on a detected voltage value that is detected by the sensor, wherein the processing circuit is configured to
identify a first elapsed time from a main switch of the vehicle being turned off until charging or discharging is started between the battery and predetermined on-board equipment,
identify a second elapsed time from starting of the charging or discharging between the battery and the on-board equipment to a current point in time, and
execute the abnormality detection processing when a total time of the first elapsed time and the second elapsed time reaches a predetermined threshold value.

2. The monitoring device according to claim 1, wherein the on-board equipment is equipment in which the charging or discharging with respect to the battery is carried out at a C-rate of 0.1 C or lower.

3. The monitoring device according to claim 2, wherein the on-board equipment is equipment in which the charging or discharging with respect to the battery is carried out at a C-rate of 0.05 C or lower.

4. The monitoring device according to claim 3, wherein the on-board t is equipment in which the charging or discharging with respect to the battery is carried out at a C-rate of 0.01 C or lower.

5. The monitoring device according to claim 1, wherein
the on-board equipment is a solar charging system, and
the charging or discharging between the battery and the on-board equipment is charging the battery from the solar charging system.

6. The monitoring device according to claim 1, wherein
the on-board equipment is an auxiliary battery, and
the charging or discharging between the battery and the on-board equipment is discharging from the battery to the auxiliary battery.

7. The monitoring device according to claim 1, wherein
the on-board equipment is a power feed port to external equipment, and
the charging or discharging between the battery and the on-board equipment is discharging from the battery to the power feed port.

8. The monitoring device according to claim 1, wherein
the battery includes a plurality of battery cells, and
the sensor detects the voltage value of each of the battery cells.

9. The monitoring device according to claim 8, wherein the processing circuit compares a difference between the detected voltage values in two adjacent battery cells with a predetermined determination reference value.
